(19) United States
(12) Patent Application Publication
(10) Pub. No.: US 2013/0122216 A1
(43) Pub. Date: May 16, 2013

(54) STRUCTURE OF EMBEDDED-TRACE SUBSTRATE AND METHOD OF MANUFACTURING THE SAME

(71) Applicant: Advanced Semiconductor Engineering, Inc., Kaohsiung (TW)

(72) Inventors: Shin-Luh TARNG, Austin, TX (US); Teck-Chong LEE, Kaohsiung City (TW)

(73) Assignee: Advanced Semiconductor Engineering, Inc., Kaohsiung (TW)

(21) Appl. No.: 13/734,621

(22) Filed: Jan. 4, 2013

Related U.S. Application Data
(62) Division of application No. 12/647,831, filed on Dec. 28, 2009.

(30) Foreign Application Priority Data
Mar. 17, 2009 (TW) 98108656

(51) Int. Cl. H05K 3/00

(52) U.S. Cl. CPC H05K 3/0094
USPC 427/555; 427/97.2

(57) ABSTRACT

A method of manufacturing an embedded-trace substrate is provided. First, a core plate is provided. Next, a through hole and a plurality of trenches are formed on the core plate, wherein the through hole passes through the core plate, and the trenches are formed on the upper and the lower surfaces of the core plate. Then, the core plate is subjected to one-plating step for electroplating a conductive material in the through hole and the trenches at the same time. Afterwards, the excess conductive material is removed.

This application is a divisional application of co-pending U.S. application Ser. No. 12/647, 831, filed Dec. 28, 2009, which claims the benefit of Taiwan application Serial No. 98108656, filed Mar. 17, 2009. These related applications are incorporated herein by reference.

### BACKGROUND OF THE INVENTION

1. Field of the Invention

The invention relates in general to a structure of embedded-trace substrate and method of manufacturing the same, and more particularly to the double-layered embedded-trace substrate structure with thick resin core plate and a method of manufacturing the same.

2. Description of the Related Art

The integrated circuit (IC) package technology plays an important role in the electronics industry. An electronic packaging is for protecting and supporting circuit configuration, creating a path for heat dissipation and providing modularized standard specification for the parts. The electronic packaging 1990s mainly employs ball grid array (BGA) packaging which is excellent in heat dissipation, has excellent electrical properties and is capable of increasing leads and effectively reducing the surface area of the package.

As lightweight, thinness, compactness, and high efficiency have become universal requirements of consumer electronic and communication products, the chip requires superior electrical properties, a smaller overall volume, and a larger number of I/O ports. As the number of I/O ports increases, the pitch of the integrated circuit is reduced. Thus, it is very difficult to achieve a high efficiency wiring on a BGA substrate. For example, the density of I/O ports increases dramatically starting with the 0.18 μm IC node or high speed (such as 800 MHz above) IC design. The flip chip technology, having high I/O density and excellent electrical properties, is a solution to the above problem and has become one of the mainstreams in the development of electronic carriers. After 2006, the flip chip carrier is already an important project to many carrier manufacturers, and quite a large percentage of the downstream products adopt the flip chip carrier. Besides, in addition to the request of the flip chip technology, the request of systematic integration of the downstream products is also getting more and more urgent. Thus, the multi-chip module (MCM) process has an increased need of the MCM carrier. The MCM carrier and the flip chip carrier have great market potential.

Along with the increase in the need for micro-electronic system (particularly, the system size and the gain of the integrated chip), the chip scale packaging (CSP) technology becomes more and more popular. Just like the through-hole technology gradually replaced by the surface-mount packaging technology (SMT), the SMT technology is now gradually replaced by the CSP technology.

Along with the maturity in the chip scale packaging (CSP) technology, system in package (SiP), the systematic semiconductor packaging technology which is function-wise and cost-wise, has become a mainstream in packaging technology. As the product size becomes smaller and the function becomes more versatile, the SiP technology is applied to satisfy the product demands for the commercial market. The SiP technology integrates chips of different functions, passive components and other modules together, so that the electronic products have versatile functions. The SiP technology also includes different technologies such as 2-dimensional multi-chip module package and 3-dimensional stacked package which stacks chips of different functions for saving space. What type of packaging technology most suitable for the chips integrated on the substrate depends on the actual design needs of the application. The SiP technology has a wide range of definition, and employs many types of bonding technologies such as wire bonding, flip-chip bonding and hybrid-type bonding.

For example, the dies with different digital or analogue functions can be bonded on a chip carrier through bumps wires. The chip carrier having embedded passive components or traces possesses electrical properties and is so-called as an integrated substrate or functional substrate. Referring to FIG. 1, which illustrates a conventional integrated embedded-trace substrate. As shown in FIG. 1, the conventional substrate has a first conductive layer 12 and a second conductive layer 13 on the lower and upper surfaces of a central core 11, respectively. The conductive layer, such as a copper layer, is patterned to form the trace pattern of the integrated substrate. Glass fiber reinforced resin could be used as the central core 11, and prepared by mixing the glass fiber (as reinforcing material) well with the resin. In the step of patterning the conductive layer, the through holes could be simultaneously formed. For example, the through holes 121 and 122 are formed in the first conductive layer 12, and the through holes 131 and 132 and the trench 133 are formed in the second conductive layer 13, as shown in FIG. 1. However, in the conventional type of integrated embedded-trace substrate of FIG. 1, the conductive pattern is projected from the central core 11 so the entire upper and the lower surfaces of the core plate are uneven. Moreover, the overall thickness of the integrated substrate (including the central core 11 and the first and the second conductive layers 12 and 13) is large and has rare chance to be thinned further if manufactured using the conventional method. Thus, the conventional integrated substrate structure as demonstrated in FIG. 1 is not suitable to be adopted in a small-sized product. As the requirements of miniature and slimness are getting higher and higher, the product using the conventional substrate structure cannot satisfy the market requirements.

### SUMMARY OF THE INVENTION

The invention is directed to an embedded-trace substrate structure and a method of manufacturing the same. A thick resin core plate is used for manufacturing a substrate structure with a uniform and smooth surface and a reduced overall thickness. The thinner appearance of the substrate of the invention indeed meets the requirements of products such as light weight, slimness and compactness in the commercial market.

According to a first aspect of the present invention, a method of manufacturing an embedded-trace substrate is provided. In one embodiment, the method comprises the following steps. Firstly, a core plate is provided. The core plate comprises a central core, a first resin layer and a second resin layer. The first and second resin layers are respectively formed on a top side and a bottom side of the central core. Next, a through hole and a plurality of trenches are formed on the core plate, wherein the through hole passes through the core plate, and the trenches are formed on the upper and the lower surfaces of the core plate respectively. Then, the core plate is subjected to one-plating step, for electroplating a conductive material in the through hole and the trenches at the same time. Afterwards, the excess conductive material is removed from the upper surface and the lower surface of the core plate so that surfaces of the conductive material filling in the through hole and the trenches are respectively coplanar with the upper surface and the lower surface of the core plate.

According to a second aspect of the present invention, a double-layered embedded-trace substrate structure is provided. The double-layered embedded-trace substrate structure comprises a central core, a first resin layer, a second resin layer, and a conductive material. The central core comprises a glass fiber-reinforced resin layer. The first resin layer and the second resin layer are formed on the upper and the lower surfaces of the central core, respectively. The first resin layer and the second resin layer have a plurality of trenches respectively. In one embodiment, an aspect ratio of a trench width (TW) to a trench depth (TD) for each trench is in a range of about 4˜¼. Also, at least one through hole passes through the first resin layer, the central core and the second resin layer. The conductive material fills in the trenches and the through hole. The surfaces of the conductive material filling in the trenches and the through hole are coplanar with the surfaces of the first resin layer and the second resin layer.

The invention will become apparent from the following detailed description of the non-limiting embodiments. The following description is made with reference to the accompanying drawings.

### BRIEF DESCRIPTION OF THE DRAWINGS

FIG. 1 (Prior Art) shows a conventional integrated embedded-trace substrate;

FIG. 2A˜FIG. 2G show a manufacturing method of an embedded-trace substrate of an embodiment of the invention; and

FIG. 3 shows a partial enlargement of a thick resin core plate according to an embodiment of the invention.

### DETAILED DESCRIPTION OF THE INVENTION

The invention provides a structure of embedded-trace substrate and a method of manufacturing the same. First, a surface of a thick resin core plate is patterned to form a through hole and a plurality of trenches for example. Next, one-plating step is applied for electroplating the through hole and the trenches with a conductive material at the same time. Then, the surface of the conductive material filling in the through hole and the trenches is processed to be coplanar with the surface of the core plate. Next, formation of solder mask layers and a surface treatment are conducted to complete an embedded-trace substrate of the invention. The embedded-trace substrate of the invention has reduced overall thickness, and the surface of the core plate is uniform and smooth (i.e. no conductive traces rising from the surface), which is very suitable to be used in small-sized products.

An embodiment is disclosed below for elaborating the manufacturing method of the embedded-trace substrate of the invention. However, the method disclosed in the following embodiments is for exemplification only, not for limiting the scope of protection of the invention. Moreover, only key elements relevant to the technology of the invention are illustrated, and secondary elements are omitted for highlighting the technical features of the invention.

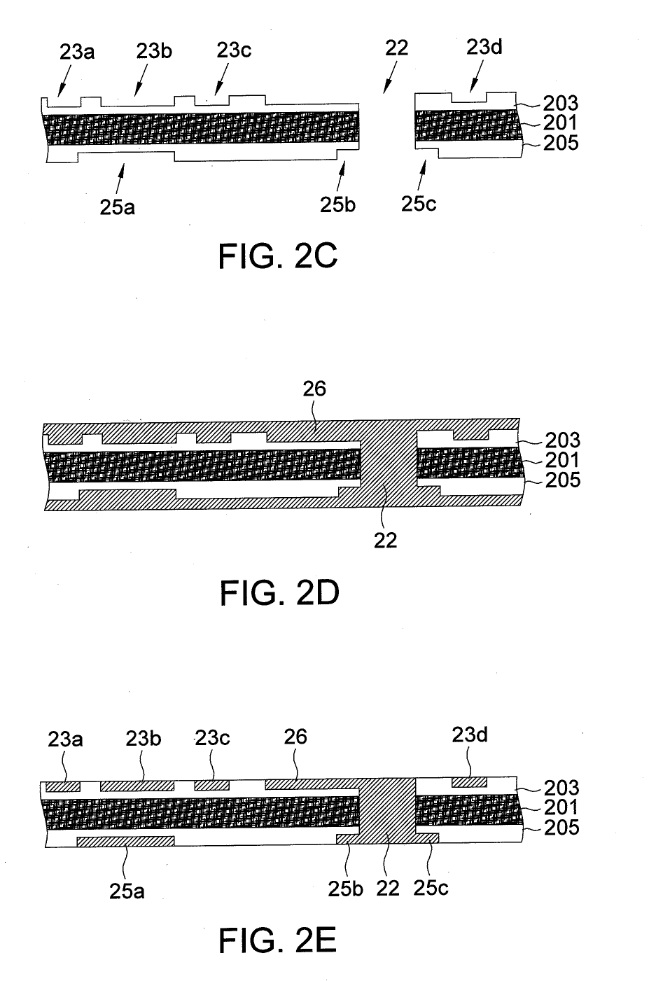

FIG. 2A˜FIG. 2G illustrate a manufacturing method of an embedded-trace substrate of an embodiment of the invention. First, a core plate, such as a thick resin core plate (TRC) 20, is provided as shown in FIG. 2A. The thick resin core plate 20 includes a central core 201, a first resin layer 203 and a second resin layer 205. In one embodiment, the central core 201 at least comprises a glass fiber-reinforced resin layer whose thickness is in a range of about 10 μm˜50 μm. The number of the glass fiber-reinforced resin layer is optionally determined according to actual needs. For example, the central core 201 can have two or three layers of glass fiber-reinforced resin. The first resin layer 203 and the second resin layer 205 respectively are formed on the upper surface and the lower surface of the central core 201, and the thicknesses of the first resin layer 203 and the second resin layer 205 are in a range of about 10 μm˜50 μm, respectively. If the central core 201 has only one glass fiber-reinforced resin layer and the thickness thereof is the minimum, that is, 10 μm, and the thickness the first resin layer 203 and that of the second resin layer 205 respectively are the minimum, that is, 10 μm, then the overall thickness of thick resin core plate is only about 30 μm. If the central core 201 has three layers of the glass fiber-reinforced resin layer and each layer has a thickness of about 50 μm, and thickness the first resin layer 203 and that of the second resin layer 205 respectively are about 50 μm, then the overall thickness of thick resin core plate is about 250 μm. Thus, the overall thickness of the thick resin core plate ranges between 30 μm˜250 μm, approximately.

The thick resin core plate 20 could be prepared by the following steps. First, the glass fiber is mixed well with the resin to produce the glass fiber-reinforced resin for being a central core 201. Next, the first resin layer 203 and the second resin layer 205 are formed at the outer surfaces of the central core 201. On the part of the central core 201, the glass fiber-reinforced resin layer and the first resin layer and the second resin layers 203 and 205 comprise a resin material, such as ammonium bifluoride (ABF), bismaleimide (BT), glass cloth epoxy (FR4, FR5), polyimide (PI), liquid crystal polymer (LCP), or epoxy. The invention does not impose particular restrictions regarding what the resin material is made of.

Next, a through hole and a plurality of trenches are formed on the thick resin core plate 20 of FIG. 2A, wherein the through hole passes through the core plate 20, and the trenches are formed on the upper surface 21a and the lower surface 21b of the core plate 20.

In this embodiment, the through hole 22, which passes through the core plate 20 as shown in FIG. 2B, is formed first. Then, the discarded scraps of glass fiber and resin generated during the formation of the through hole 22 are removed by proceeding a cleaning step. Next, a plurality of trenches 23a˜23d and 25a˜25c are formed on the first resin layer 203 and the second resin layer 205 respectively, as shown in FIG. 2C. Afterwards, the discarded resin scraps generated during the formation of the trenches 23a˜23d, 25a˜25c are removed by proceeding a cleaning step. It is noted that the sequence of forming the through hole 22 and the trenches 23a˜23d, 25a˜25c might have a considerable effect on the electrical characteristics of the product. If the trenches 23a˜23d, 25a˜25c are formed first and the through hole 22 is formed next, the unwanted scraps or particles of glass fiber and resin generated during the drilling of the through hole 22 may fall into the trenches 23a˜23d, 25a˜25c, and have an effect on the subsequent processes and electrical property of the product. It might require extra steps for taking care of this partical pollution. However, the invention does not specify the sequence regarding the formations of the through hole 22 and the trenches 23a˜23d, 25a˜25c.

In the present embodiment of the invention, the through hole 22 as shown in FIG. 2B can be formed by mechanical drilling or laser drilling the core plate 20. If the laser drilling method is selected, a long wavelength laser light with higher energy, such as CO₂ laser, can be used to form the through hole 22 on the core plate 20. Also, a short wavelength laser light with lower energy, such as a UV light or an excimer laser, could be used to form the trenches 23a˜23d, 25a˜25c on the first resin layer 203 and the second resin layer 205, as shown in FIG. 2C. Instead of using the conventional photolithography procedure, a laser method with high precision positioning system adopted herein for forming the through hole 22 and the trenches 23a˜23d, 25a˜25c has advantage of self-alignment, so that the products manufactured by the method of the embodiment has self-aligned features and accurate patterns.

Next, as shown in FIG. 2D, the core plate 20 is subjected to one-plating step. For example, the core plate 20 is immersed in an electrolysis bath for electroplating the through hole 22 and the trenches 23a˜23d, 25a˜25c with a conductive material 26 at the same time. In one embodiment, the conductive material 26 is made of copper. Unlike the conventional method of electroplating the holes /the trenches which must form a bottom copper by way of electroless deposition first and then fill in the entire space by way of electroplating next, the through hole 22 and the trenches 23a˜23d, 25a˜25c of the embodiment can be quickly filled up with the conductive material 26 in one-plating step. It not only shortens the overall cycle time of whole procedures, but also decreases the manufacturing cost.

Afterwards, as shown in FIG. 2E, the excess conductive material 26 on the upper surface 21a and the lower surface 21b of the core plate 20 is removed so that the surfaces of the conductive material 26 filling in the through hole 22 and the trenches 23a˜23d, 25a˜25c are coplanar with the upper surface 21a and the lower surface 21b of the core plate 20. In the present embodiment, the surface of the conductive material 26 can be thinned by way of etching or mechanical grinding for removing the excess conductive material 26 from the core plate 20. Also, the excess conductive material can be planarized by way of electrolytic thinning, flash etching, surface ablation/plasma cleaning or other related techniques. The invention does not impose particular restriction thereto.

Then, a first solder mask layer 206 and a second solder mask layer 207 are formed on the upper surface 21a and the lower surface 21b of the core plate 20, respectively. The first solder mask layer 206 and the second solder mask layer 207 respectively expose a partial surface of the conductive material 26 filling in the through hole 22 and the trenches. As shown in FIG. 2F, the first solder mask layer 206 exposes a partial surface of the conductive material 26 filling in the trenches 23b, and the second solder mask layer 207 exposes a partial surface of the conductive material 26 filling in the trenches 25a˜25c. In one embodiment, the thickness of the first solder mask layer 206 and that of the second solder mask layer 207 are in a range of about 10 μm 20 μm, respectively.

In the present embodiment, after the first solder mask layer 206 and the second solder mask layer 207 are formed, a surface treatment is applied to the exposed surfaces of the conductive material 26 filling in the through hole 22 and the trenches 23b, 25a˜25c. For example, a bus-less metal finish process is applied to correspondingly form a plurality of metal layers 208a˜208c or a metal protection layer as shown in FIG. 2G so as to complete the manufacture of the embedded-trace substrate. In one embodiment, the metal layers 208a˜208c (or the metal protection layer) are made of the materials which have less harmful even no pollution to the environment, such as leadless solder. The leadless solder comprises a metal coating layer and an organic coating layer. The metal coating layer contains electroless nickel/immersion gold (ENIG), immersion silver (ImAg), immersion tin (ImSn) or selective tin-plating for example, and the organic coating layer (the metal protection layer) contains organic solderability preservative (OSP). However, the invention is not limited thereto, and the selection of the material for conducting the surface treatment is determined according to the needs of practical applications.

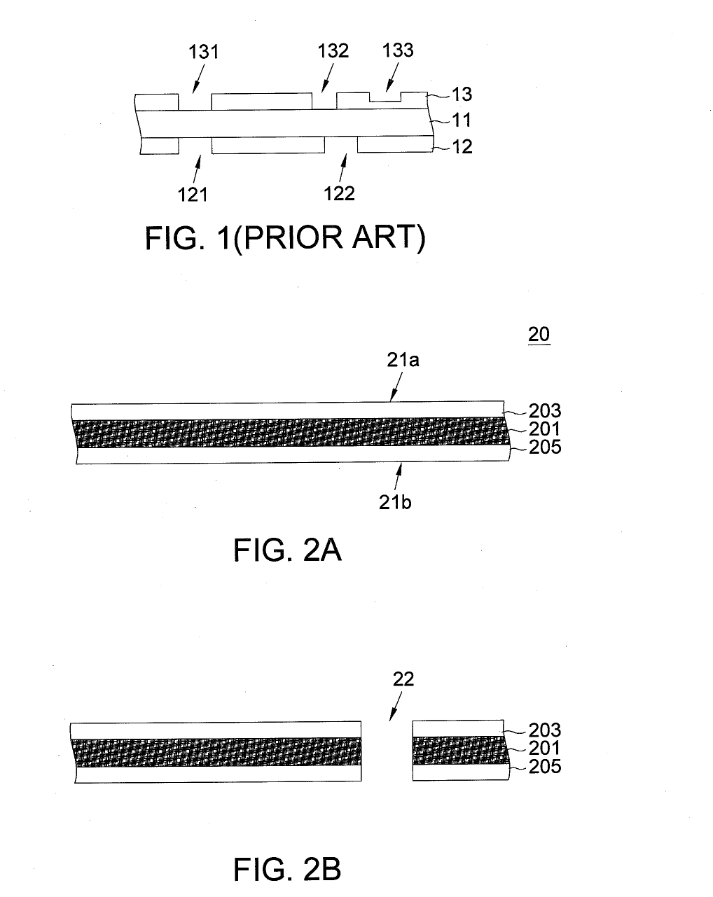

According to the method of manufacturing an embedded-trace substrate disclosed in the above embodiment, the trenches are directly defined on the resin and the through hole is formed on the resin (i.e. the first resin layer 203 and the second resin layer 205) of the thick resin core plate 20, and the trace pattern (as shown in the conductive material 26 of FIG. 2E) of the core plate can be exposed and coplanar with the surface of the resin as long as the excess conductive material is removed for planarizing the surface of the conductive material. Compared with the conventional embedded-trace substrate structure (as indicated in FIG. 1), the core plate manufactured according to the method of the embodiment has a uniform and smooth (i.e. planar) profile, and no conductive trace raises form the outer surface of the substrate structure. Moreover, the overall thickness of the thick resin core plate disclosed in the above embodiments ranges about 30 μm˜250 μm. Also, the overall thickness of the embedded-trace substrate of the embodiment, which is the thickness of the thick resin core plate 20 plus the thicknesses of the first solder mask layer 206 and the second solder mask layer 207 (respectively about 10 μm˜20 μm), is in a range of about 50 μm 290 μm. Thus, the embedded-trace substrate manufactured according to the method of the embodiment has a planar surface, and the overall thickness can be reduced significantly to be no more than 290 μm. It indeed satisfies the requirements of light weight, slimness and compactness to commercial products.

The embodiment further investigates the effect of the sizes and the shapes of the trenches (formed on the resin layer as shown in FIG. 2C) on the product.

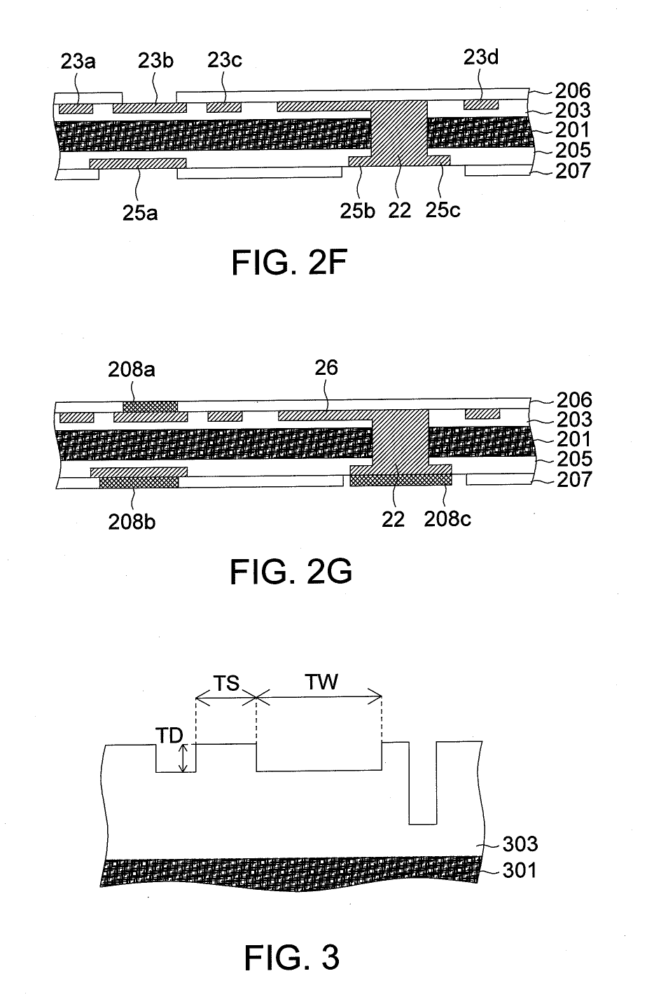

Referring to FIG. 3, a partial enlargement of a thick resin core plate according to an embodiment of the invention is shown. The first resin layer 303 disposed above the central core 301 has many trenches. FIG. 3 shows three parameters relevant to the size of the trenches, namely, the trench wall thickness TS, the trench width TW and the trench depth TD. The values of the three parameters have significant effects on the characteristics of the final products. For example, if the trench wall is too thin (i.e. TS too small), the trench wall is likely to be damaged in the subsequent processes. If the trench is too wide (i.e. TW too large), the subsequent process of electroplating and planarizing the conductive material will be difficult to be conducted. Also, the trench depth TD is subjected to resin layer thickness and the electroplating capability of the conductive material.

According to an embodiment, the aspect ratio of the trench width to the trench depth (TW/TD) of each trench is in a range of about 4˜¼. On the part of the embedded-trace substrate of the embodiment, the conductive material fills in the trenches to form a pattern of conductive traces, so the aspect ratio of TW/TD of the trench affects the signal integrity of the circuit. The trenches can have the same or different aspect ratios, and the exact value of the aspect ratio of TW/TD to each trench should be determined according to actual needs of practical application, as understood by people skilled in the art. For example, if the trenches of the embodiment are formed in the application of a guardband circuit, a lower value of aspect ratio of TW/TD for each trench such as ½ or less than 1 is selected. If the trenches of the embodiment are formed in the application of a conducting circuit, a higher value of aspect ratio of TW/TD for each trench such as 2 or larger than 1 is selected.

In one embodiment, each trench wall thickness TS is in a range of about 5 μm˜15 μm or 5 μm˜12 μm, and each trench width TW is in a range of about 5 μm˜15 μm or 5 μm˜12 μm. As for the core plate (referring to FIG. 2F) which selects the first solder mask layer and the second solder mask layers 206 and 207 whose thickness respectively being in a range of 10 μm˜20 μm, the trench depth TD could be determined in a range of about 5 μm˜12 μm.

Moreover, the aspect ratio of the trench wall thickness TS to the trench depth TD affects the strength of the trench wall, product yield rate and product reliability (such as occurrence of current leakage or cross-talking). In one embodiment, the aspect ratio of TW/TD for each trench is in a range of about 4˜¼. However, the invention does not impose any particular restrictions thereto, and the exact value is determined according to actual requirements of design. For example, if the substrate of the embodiment for the application requires the embedded trace with high reliability and produced in high standard yield rate, a higher aspect ratio of TS/TD such as 2, and 15 μm of the trench wall thickness TS may be optionally selected. If the substrate of the embodiment for the application does not require high yield rate production and the embedded trace with high reliability, a lower aspect ratio of TS/TD such as ½ (or above), and 5 μm (or above) of the trench wall thickness TS may be optionally selected.

To summarize, according to the method of manufacturing an embedded-trace substrate of the embodiment, the trenches are directly defined and the through hole is formed on the resin of a thick resin core plate. Also, one-plating step is applied for electroplating the trenches and the through hole with a conductive material at the same time. The trace pattern of the core plate is formed after the excess conductive material is removed and the surface is planarized. The surface of the conductive material is coplanar with the surface of the resin. Thus, the embedded-trace substrate manufactured according to an embodiment of the invention has a smooth and uniform surface, and the overall thickness is largely reduced. It indeed satisfies the requirements of light weight, slimness and compactness to the commercial products.

While the invention has been described by way of example and in terms of an embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method of manufacturing an embedded-trace substrate, comprising:
providing a core plate, comprising:
a central core; and
a first resin layer and a second resin layer, respectively formed on a top side and a bottom side of the central core;
forming a through hole and a plurality of trenches in the core plate, wherein the through hole passes through the core plate, and the trenches are formed on an upper surface and a lower surface of the core plate;
applying one-plating step to the core plate for electroplating the through hole and the trenches with a conductive material at the same time; and
removing the excess conductive material from the upper surface and the lower surface of the core plate so that surfaces of the conductive material filling in the through hole and the trenches are coplanar with the upper surface and the lower surface of the core plate.

2. The manufacturing method according to claim 1, wherein the central core comprises at least one glass fiber-reinforced resin layer.

3. The manufacturing method according to claim 1, wherein the glass fiber-reinforced resin layer, the first resin layer and the second resin layer comprise a resin material selected from ammonium bifluoride (ABF), bismaleimide (BT), glass cloth epoxy (FR4, FR5), polyimide (PI), liquid crystal polymer (LCP) or epoxy.

4. The manufacturing method according to claim 1, wherein the through hole passing through the core plate is formed before formation of the trenches on the first resin layer and the second resin layer.

5. The manufacturing method according to claim 4, wherein a long wavelength laser light is used for laser drilling the core plate to form the through hole.

6. The manufacturing method according to claim 4, wherein a short wavelength laser light is used for laser cutting the first resin layer and the second resin layer to define the trenches.

7. The manufacturing method according to claim 1, wherein an aspect ratio of a trench width (TW) to a trench depth (TD) for each trench is in a range of about 4˜¼.

8. The manufacturing method according to claim 7, wherein the trench width of each trench is in a range of about 5 μm˜15 μm.

9. The manufacturing method according to claim 7, wherein a trench wall thickness of each trench is in a range of about 5 μm˜15 μm.

10. The manufacturing method according to claim 1, wherein the core plate is immersed in an electrolysis bath for electroplating the through hole and the trenches with the conductive material at the same time.

11. The manufacturing method according to claim 1, further comprising:
forming a first solder mask layer and a second solder mask layer on the upper surface and the lower surface of the core plate respectively, wherein the first solder mask layer and the second solder mask layer respectively expose a partial surface of the conductive material in the through hole and the trenches.

12. The manufacturing method according to claim 11, wherein a thickness of the first solder mask layer and that of the second solder mask layer respectively are in a range of about 10 μm˜20 μm.

13. The manufacturing method according to claim 11, wherein after the first solder mask layer and the second solder mask layer are formed, the method further comprises:
applying a surface treatment to the exposed surface of the conductive material filling in the through hole and the trenches to form a metal layer or a metal protection layer.
